(19) United States
(12) Patent Application Publication
(10) Pub. No.: US 2008/0213942 A1
(43) Pub. Date: Sep. 4, 2008

(54) Method for fabricating semiconductor device and carrier applied therein

(75) Inventors: Min-Shun Hung, Taichung Hsien (TW); Ho-Yi Tsai, Taichung Hsien (TW); Chien-Ping Huang, Taichung (TW); Wen-Tsung Tseng, Taichung (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/074,321

(22) Filed: Mar. 3, 2008

(30) Foreign Application Priority Data
Mar. 3, 2007 (TW) 096107332

(51) Int. Cl. H01L 23/12; H05K 7/00

(52) U.S. Cl. 438/108; 438/118; 438/119; 361/820; 257/E23.003

(57) ABSTRACT

This invention provides a method for fabricating a semiconductor device and a carrier applied therein. The method includes the steps of: disposing a chip-mounted substrate in an opening of a carrier; forming at least a storage aperture and at least an inspection aperture in the carrier; infusing an adhesive into the storage aperture to fill a gap between the substrate and carrier with the adhesive by capillarity; determining whether the inspection aperture is filled with the adhesive to ascertain whether the gap is completely filled with the adhesive; in response to a positive result, performing a molding process to form a molding compound for encapsulating the chip; and performing implantation of solder ball and a singulation process to form a semiconductor device with desirable dimensions. The inspection aperture is inspected with a naked eye to determine whether the gap is completely filled with the adhesive, thereby reducing inspection costs and increasing yields of products with no additional packaging costs.

### BACKGROUND OF THE INVENTION

1. Field of the Invention

The present invention relates to a semiconductor process, and more particularly, to a method for fabricating a semiconductor device and a carrier applied therein.

2. Description of the Prior Art

A conventional Flip-Chip Ball Grid Array (FCBGA) semiconductor package essentially comprises a substrate, a chip electrically connected to the top surface of the substrate by flip chip technique, and a plurality of solder balls implanted on the bottom surface of the substrate and electrically connected to the outside. The package further comprises a molding compound formed on the top surface of the substrate by a molding process and configured to encapsulate the chip. U.S. Pat. Nos. 6,038,136, 6,444,498, 6,699,731 and 6,830,957 have disclosed the prior art, and have taught a similar package.

As disclosed in U.S. Pat. No. 6,830,957, a process of the Flip-Chip Ball Grid Array (FCBGA) semiconductor package comprises the step of extending a clamp area from the periphery of the substrate longitudinally and transversely, such that the substrate is bigger than the cavity of the mold and can be firmly clamped by the mold. As a result, the molding compound rarely flashes over to the back of the substrate and endangers the bonding characteristic of the ball pads for implanting solder balls on the substrate. However, a drawback of the prior art is an increase in the dimensions of the substrate, which in turn, increases packaging costs greatly (normally, a substrate for use with a flip chip accounts for more than 60% of the total cost of a package). Moreover, the releasing step (configured for die separation) following the molding process cannot be smoothly performed, unless the cavity of the mold is shaped in a way as to allow the margin of the molding compound on the substrate to assume a releasing angle. In general, to facilitate releasing, the releasing angle has to be less than 60°. Similarly, the releasing angle is implemented at the cost of substrate enlargement, thus decreasing substrate utilization and increasing the overall cost by 15-20%.

The aforesaid problems together pose a dilemma to the process of a ball grid array semiconductor package. On one hand, a molding process of a molding compound is indispensable to fabrication of packages; on the other hand, the molding process accounts for substrate enlargement and high costs, and is therefore unfavorable to mass production a ball grid array semiconductor package. Obviously, the unresolved issue is the bottleneck of developing a flip-chip ball grid array semiconductor package.

Referring to FIGS. 1A to 1D, which are schematic views showing a method for fabricating a semiconductor package disclosed in Taiwanese Patent Nos. 1244145 and 1244707 filed by the applicants of the present patent application, the method comprises the steps of: preparing a plurality of substrates 10 and a carrier 16, wherein the dimensions of the substrates 10 approximate to the predetermined dimensions of a semiconductor package, each of the substrates 10 is mounted with a chip 11, the carrier 16 is formed with a plurality of openings 160, the dimensions of the openings 160 exceed those of the substrates 10 to allow the substrates 10 to be secured in position in the openings 160 of the carrier 16, a gap 17 between the substrates 10 and the carrier 16 is sealed so that the gap 17 does not penetrate the carrier 16 (as shown in FIG. 1A); performing a molding process for providing each of the openings 160 with a molding compound 13 to encapsulate the chip 11, wherein the molding compound 13 covers an area larger than that of each of the openings 160 (as shown in FIG. 1B); implanting, upon completion of releasing, a plurality of solder balls 12 on the back of the substrates 10 (as shown in FIG. 1C), cutting the substrates 10 along the periphery thereof according to the predetermined dimensions of the semiconductor package (as shown in FIG. 1D) so as to form a plurality of semiconductor packages. Given the aforesaid favorable features, namely, sealing the gap 17 between the substrates 10 and the carrier 16 to prevent the molding compound 13 from flashing over and making the projection dimensions of the cavity for the molding compound 13 greater than those of the openings 160 to facilitate releasing, known drawbacks, such as the problems with flash-over and releasing, can be solved without increasing the dimensions of the substrates 10; and the resultant dimensions of the substrates 10 approximate to the predetermined dimensions of a semiconductor package, thus preventing waste of substrate material which might otherwise arise from cutting.

Referring to the aforesaid process again, to effectively position the substrates 10 and seal the gap 17 between the substrates 10 and carrier 16, the gap 17 is dispensed and filled with a solder mask, such as an adhesive 18, an epoxy resin, or any polymer. To speed up the dispensing operation, at the beginning, the gap 17 must be at least 1 mm wide, in order to be swiftly filled with the adhesive 18 in a pen-write manner. However, the wider the gap 17 gets, the more the adhesive 18 is required. Increased amounts of the adhesive 18 lead to increased costs. In addition, when oversized, the gap 17 predisposes the substrates 10 adhered to a tape beforehand, to shift away from their predetermine positions, thus causing more problems to the subsequent process. For instance, the shift of the substrates 10 results in a discrepancy between two adjacent gaps, and consequently one is not completely filled with the adhesive, but the other is prone to a flash-over (as shown in FIG. 2A). Even worse, the flashed-over gap contributes to delamination of the subsequently formed molding compound 13 from the substrates 10, in the presence of the residual adhesive 18 therebetween (as shown in FIG. 2B). Conversely, when undersized, the gap 17 prevents the substrates 10 from shifting, and can only be completely filled with the adhesive 18 by a thinner dispenser needle at a lower dispensing speed. However, the low dispensing speed incurs high process costs.

Referring to FIG. 3, which is a schematic view showing a method for fabricating a semiconductor package proposed in Taiwanese Patent Application No. 95133420 filed by the applicants of the present patent application, the method comprises the steps of: disposing a substrate 20 mounted with a chip 21 in an opening 260 of a carrier 26, wherein the opening 260 is slightly larger than the substrate 20 and thus a gap S is formed between the substrate 20 and carrier 26; forming a storage aperture 261 at the periphery of the opening 260 of the carrier 26, so as to keep the gap S as narrow as possible, minimizing the amount of an adhesive C required to fill the gap S, and completely filling the gap S with the adhesive C before the molding process begins; and infusing the adhesive C into the storage aperture 261, so as to fill the gap S between the substrate 20 and carrier 26 with the adhesive C by capillarity.

To allow the gap to be filled, by capillarity, with the adhesive infused into the storage aperture, the gap is 0.05 to 0.2 mm wide, and preferably 0.1 mm wide. The specified width not only enables capillarity and saves adhesive, but also ensures that the substrate is precisely positioned in the opening. Nevertheless, it is impossible to determine whether a narrow gap is completely filled with an adhesive by inspecting with a naked eye; instead, a 30× microscope is required. However, microscopic inspections are both complex and expensive. Chances are, during a molding process, a molding compound escapes from a gap not inspected with a microscope and not completely filled with an adhesive and eventually flashes over to the back of the substrate, thus contaminating the ball pads and compromising the yield of finished products.

Accordingly, it is important to develop a method for fabricating a semiconductor device and a carrier applied therein, and determining whether a gap is completely filled with an adhesive through inspection with a naked eye instead of a microscope, preventing a molding compound from escaping from a gap and not completely filled with an adhesive, flashing over to the back of a substrate, contaminating ball pads, and compromising yield of finished products.

### SUMMARY OF THE INVENTION

In light of the aforesaid drawbacks of the prior art, it is a primary object of the present invention to disclose a method for fabricating a semiconductor device and a carrier applied therein, to allow a gap between the substrate and a carrier to be inspected with a naked eye rather than a microscope, and determine whether the gap is completely filled with an adhesive.

It is another object of the present invention to disclose a method for fabricating a semiconductor device and a carrier applied therein, to lower inspection costs and to simplify the process.

It is a further object of the present invention to disclose a method for fabricating a semiconductor device and a carrier applied therein, to ensure that the gap between the substrate and the carrier is completely filled, without increasing the inspection costs.

In order to achieve the above and other objects, the present invention discloses a method for fabricating a semiconductor device, comprising the steps of: disposing a chip-mounted substrate in an opening of a carrier, wherein a gap with a desirable width is formed between the substrate and the carrier, and at least a storage aperture and at least an inspection aperture are formed at the periphery of the opening of the carrier; infusing an adhesive into the storage aperture, thus filling the gap and inspection aperture with the adhesive by capillarity; inspecting the inspection aperture to determine whether the inspection aperture is filled with the adhesive; forming, in response to a positive result, a molding compound on the substrate and carrier to encapsulate the chip and the opening; and performing a singulation process to form a semiconductor device with desirable dimensions. The chip is electrically connected to the substrate by flip chip technique.

The positions and quantity of the inspection apertures are known to persons of skills in the art. The more the inspection apertures are, the more accurate the determination is as to whether the gap formed between the substrate and carrier is completely filled with the adhesive. The inspection apertures are subject to variation in size and shape. The shapes of the inspection apertures may be semicircles, rectangles, triangles, or any regular/irregular shapes. The dimensions of the inspection apertures are preferably 3 to 10 times the width of the gap; or, in other words, the radiuses or side lengths of the inspection apertures are in the range of from 0.15 to 2.0 mm, and preferably 1.0 mm, to prevent waste of adhesive and to determine whether the gap between the substrate and carrier is completely filled with the adhesive by inspecting the inspection apertures with a naked eye.

The present invention further discloses a carrier for use in the method for fabricating a semiconductor package with a plate structure as a carrier, in which an opening is penetratingly formed. At least a storage aperture and at least an inspection aperture are formed at the periphery of the opening.

### BRIEF DESCRIPTION OF THE DRAWINGS

FIGS. 1A to 1D (PRIOR ART) are schematic views showing a method for fabricating a semiconductor package disclosed in Taiwanese Patent Nos. 1244145 and 1244707;

FIGS. 2A and 2B (PRIOR ART) are cross-sectional views depicting known encapsulation-related problems in securing a substrate in position in a known carrier;

FIG. 3 (PRIOR ART) is a schematic view showing a method for fabricating a semiconductor package proposed in Taiwanese Patent Application No. 95133420 filed by the applicants of the present patent application;

FIGS. 4A to 4H are schematic views showing a method for fabricating a semiconductor device of the present invention; and

FIGS. 5 to 9 are schematic views showing various preferred embodiments of a carrier applied in a method for fabricating a semiconductor device of the present invention.

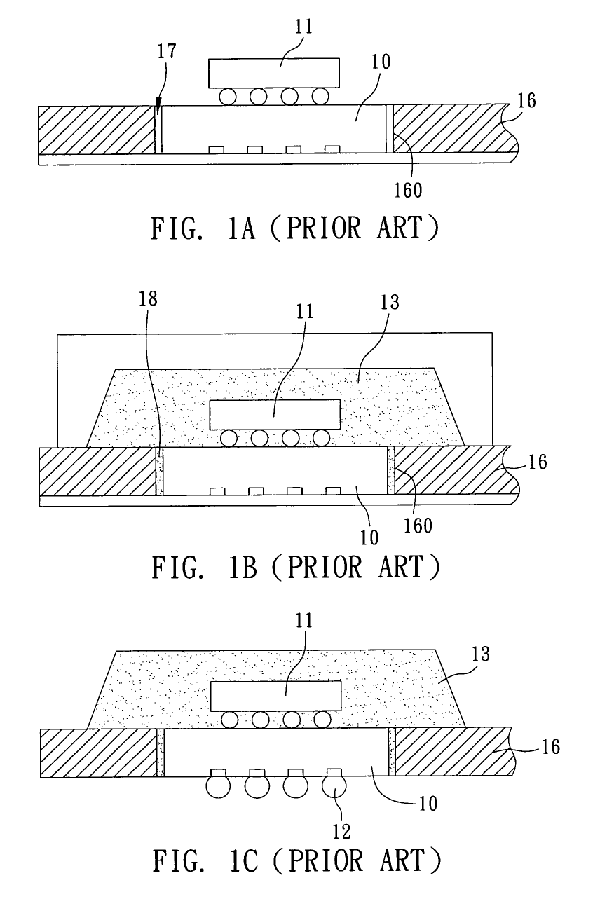

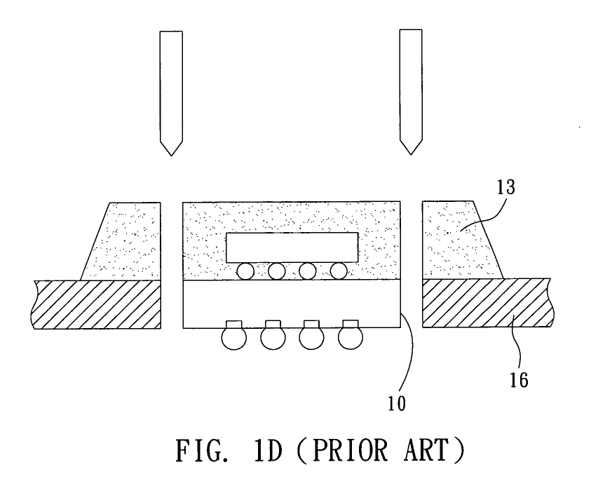

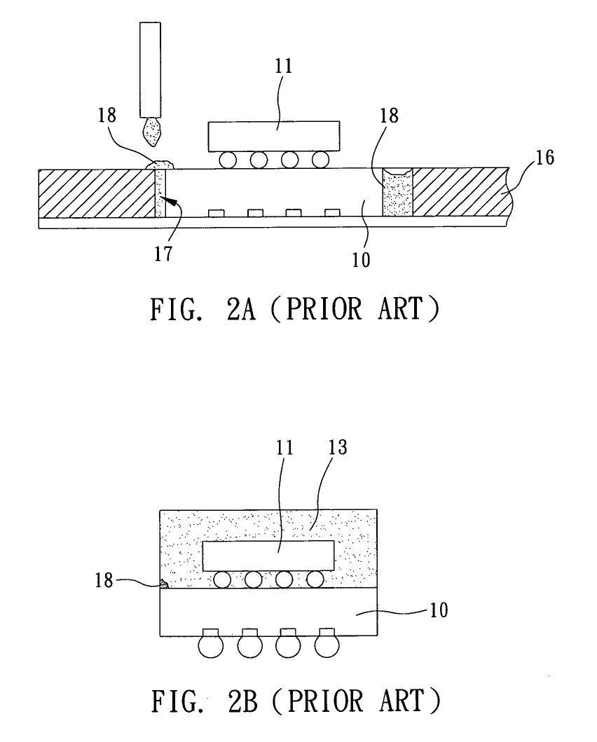

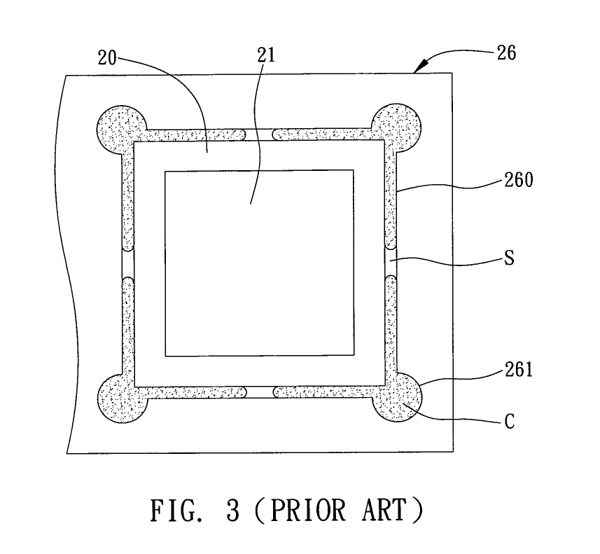

### DETAILED DESCRIPTION OF THE PREFERRED EMBODIMENTS

The following specific embodiments are provided to illustrate the present invention. Persons skilled in the art can readily gain insight into other advantages and features of the present invention based on the contents disclosed in this specification.

The present invention is put forth with a view to addressing the shortcomings of Taiwanese Patent Application No. 95133420, and thus like parts, materials, and steps are no longer described in detail in the specification of the present invention, for the sake of brevity.

Indefinite articles “a” and “an” used in this specification are not intended to limit the quantity of an ensuing object described, but to indicate that the number of the object is one or more. Where there is more than one object, the phrase “a plurality of” is used before the object. Where there is one and only one object, the word “one” or an equivalent thereto is used before the object.

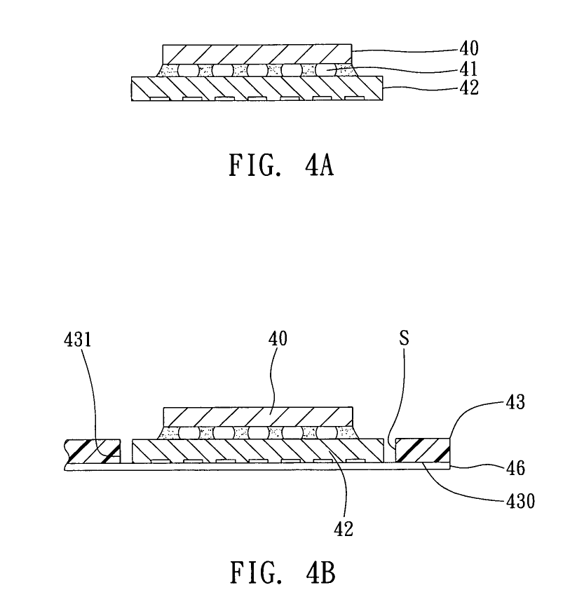

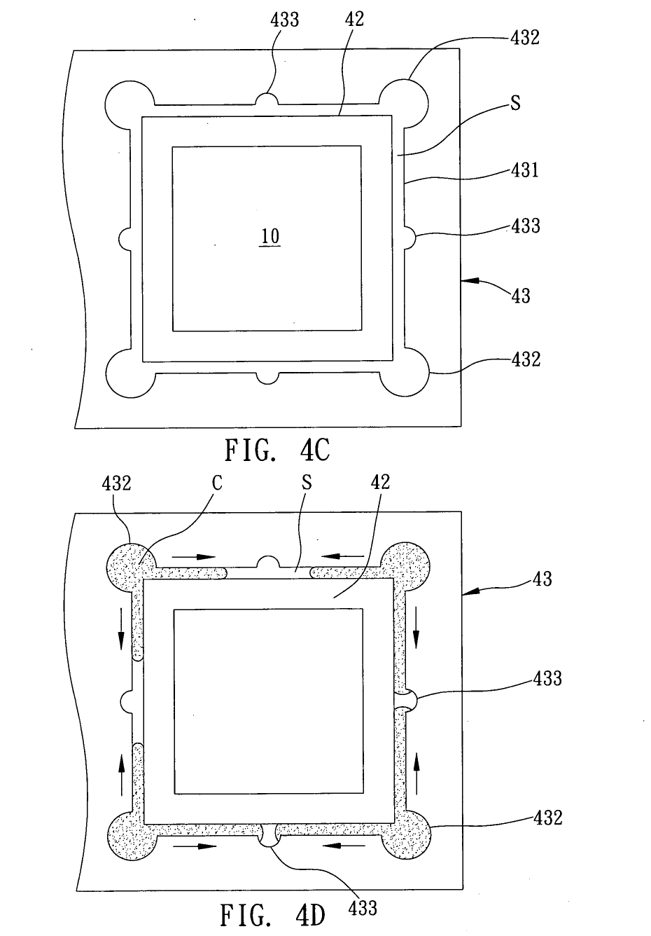

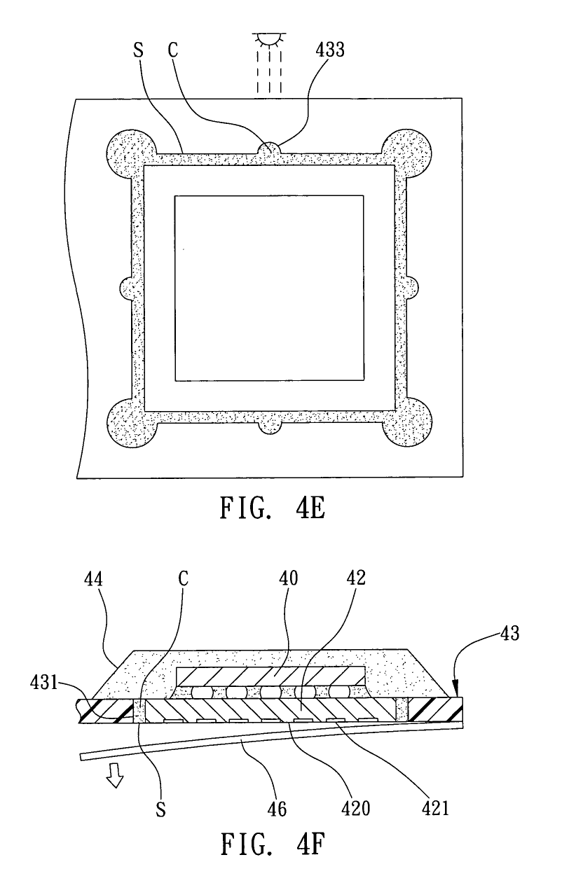

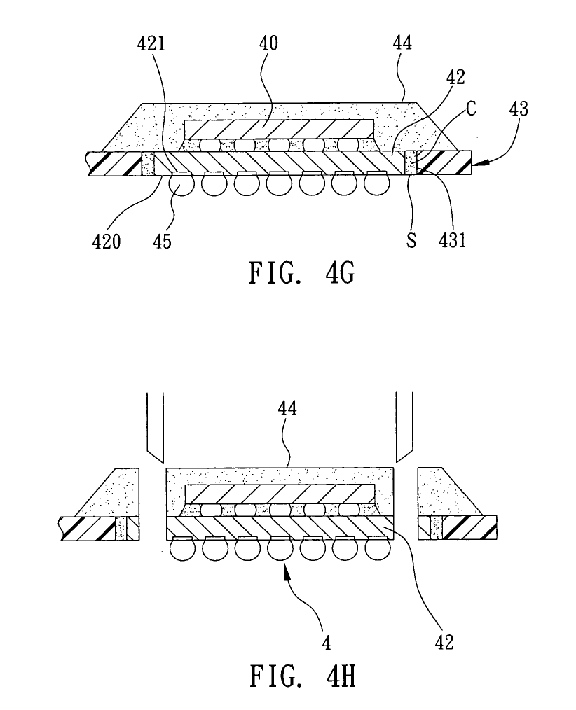

FIGS. 4A to 4H are schematic views showing a method for fabricating a semiconductor device of the present invention.

Referring to FIG. 4A, a chip 40 is soldered to a substrate 42 by means of a plurality of solder bumps 41 soldered to the chip 40, so as to electrically connect the chip 40 to the substrate 42 via the solder bumps 41. It is known in the art that a chip is electrically connected to a substrate by flip chip technique, and therefore it is not an essential technical feature of the present invention. Alternatively, the chip may be electrically connected to the substrate by wire bonding.

Referring to FIGS. 4B and 4C (wherein FIG. 4C is a top plan view of FIG. 4B), a carrier 43 provided is made of FR4, FR5, BT, or a similar polymer; a tape 46 is glued to the back 430 of the carrier 43, so as to seal one end of an opening 431 penetratingly formed in the carrier 43; and the substrate 42 mounted with the chip 40 is received in the opening 431 through the tape 46.

The opening 431 of the carrier 43 is a square. Storage apertures 432 are formed at the four corners of the opening 431. Inspection apertures 433, semicircle-shaped and spaced from the storage apertures 432 by appropriate distances, are formed at the periphery of the opening 431. The opening 431 is slightly larger than the substrate 42. A gap S with a desirable width is formed between the carrier 43 and the substrate 42 received in the opening 431. An adhesive (described later in detail) is infused into the gap S due to capillarity thereof. The gap S is desirably 0.1 mm wide, and communicates with the storage apertures 432 and inspection apertures 433.

The adhesive is infused into the storage apertures 432 by using a common dispensing device. Given appropriate dimensions, the storage apertures 432 can be swiftly infused with the adhesive, without using any expensive dispensing device equipped with a delicate dispenser needle; thus reducing costs and speeding up the process. Considering that the inspection apertures 433 are solely configured for inspection with a naked eye to determine whether the gap S is completed filled with the adhesive, the inspection apertures 433 must not be large enough to interrupt capillarity and/or increase the required amount of adhesive, or be too small to be inspected. Hence, the radiuses or the side lengths of the inspection apertures 433 are in the range of from 0.15 to 2.0 mm, depending on the shape of the inspection apertures 433. Preferably, the radiuses or side lengths of the inspection apertures 433 are 1 mm, such that the inspection apertures 433 are smaller than the storage apertures 432.

Referring to FIG. 4D, the adhesive C is infused into the storage apertures 432 by a dispensing means, so as to infuse the adhesive C into the gap S (in the directions indicated by arrows shown in the drawing) by capillarity rendered by the gap S and allow the adhesive C to be infused into the inspection apertures 433 while passing through. Once the gap S is filled with the adhesive C, the substrate 42 is secured in position in the carrier 43. Normally, the adhesive C is a solder mask, an epoxy resin, or any polymer.

Referring to FIG. 4E, the inspection apertures 433 are inspected with a naked eye to determine whether the inspection apertures 433 are filled with the adhesive C; in response to a negative result (indicating that the gap S is not completely filled with the adhesive C), proceeding to a packaging process is refrained; and in response to a positive result (indicating that the gap S is completely filled with the adhesive C), the packaging process is proceeded.

Referring to FIG. 4F, a molding process is performed to form a molding compound 44 on the carrier 43 coupled with the substrate 42. The bottom surface area of the molding compound 44 is larger than that of the opening 431, and thus the molding compound 44 completely encapsulates the substrate 42, the chip 40 mounted on the substrate 42, and the gap S. Since the gap S is completely filled with the adhesive C as described above, the molding compound 44 does not flash over to the back 420 of the substrate 42 and contaminate ball pads 421 formed on the back 420 of the substrate 42 during the molding process. As a result, quality of soldering solder balls (shown in FIG. 4G) to the ball pads 421 is ensured. Afterward, the tape 46 is removed.

Referring to FIG. 4G, implantation of a solder ball, which involves implanting a plurality of solder balls 45 to the ball pads 421 formed on the back of the substrate 42 is performed, so as to electrically connect the chip 40 to an external device via the solder balls 45.

Referring to FIG. 4H, a singulation process involving cutting the molding compound 44 and substrate 42 along a cutting line (not shown) on the substrate 42 is performed, so as to form a semiconductor device 4 with desirable dimensions. It is noteworthy that, alternatively, implantation of solder balls may be performed after singulation. The current preferred embodiment is put forth to illustrate rather than limit the present invention.

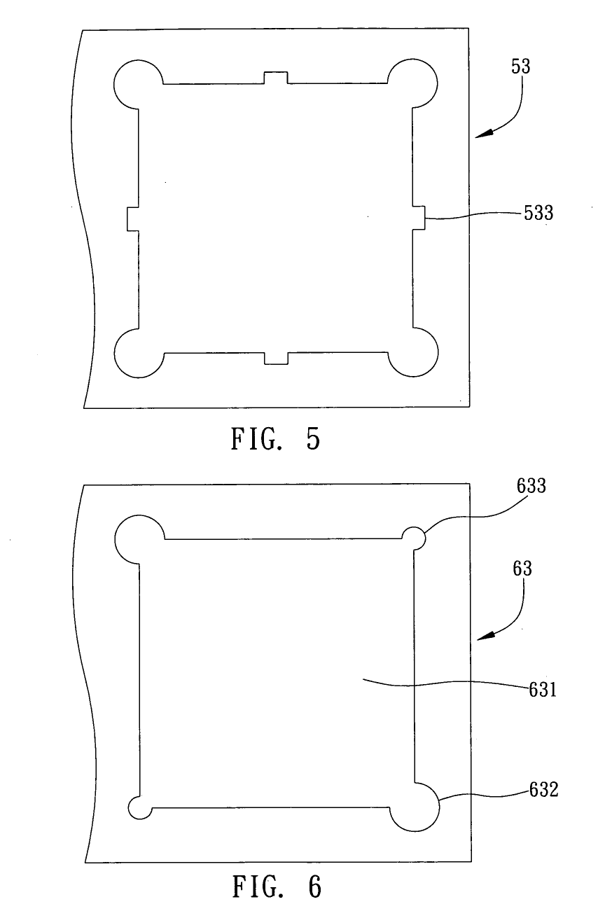

FIGS. 5 to 9 are schematic views that show various preferred embodiments of a carrier applied in a method for fabricating a semiconductor device of the present invention and illustrate, rather than limit, the positions and quantity of storage apertures and inspection apertures formed in the carrier. Preferably, each of the inspection apertures is formed equidistantly between the adjacent storage apertures, for efficient inspection, so as to efficiently determine whether the gap is filled with the molding compound.

Referring to FIG. 5, the current preferred embodiment is different from the preceding preferred embodiment in that inspection apertures 533 of a carrier 53 of the current preferred embodiment are squares; thereby each of the inspection apertures 533 has four sides with equal length of 1 mm.

Referring to FIG. 6, the current preferred embodiment is different from the preceding preferred embodiment in that two storage apertures 632 are respectively formed at two opposite corners of an opening 631 of a carrier 63 of the current preferred embodiment, and two inspection apertures 633 are respectively formed at the other two opposite corners of the opening 631 of the carrier 63.

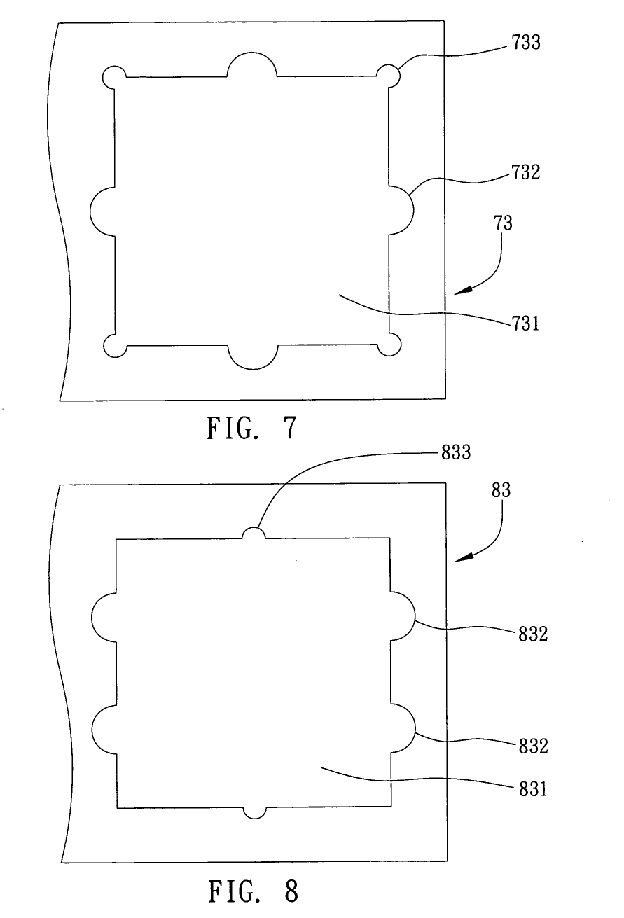

Referring to FIG. 7, the current preferred embodiment is different from the preceding preferred embodiment in that storage apertures 732 are each formed at the periphery of an opening 731 of a carrier 73 of the current preferred embodiment, and the inspection apertures 733 are each formed at the four corners of the opening 731.

Referring to FIG. 8, the current preferred embodiment is different from the preceding preferred embodiment in that inspection apertures 833 are formed centrally at two opposite sides of an opening 831 of a carrier 83 of the current preferred embodiment, and the storage apertures 832 are formed substantially centrally at the other two opposite sides of the opening 831 in pairs.

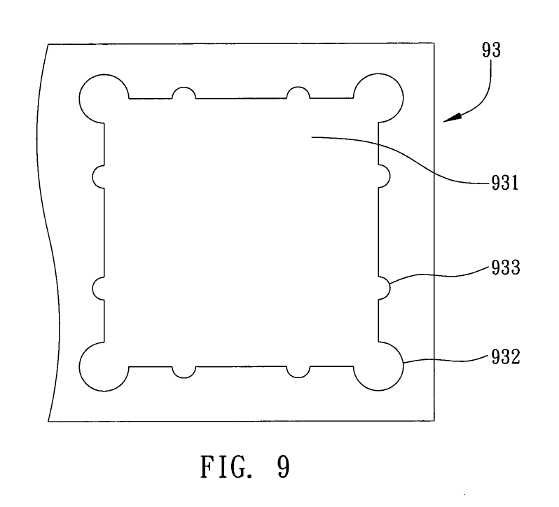

Referring to FIG. 9, the current preferred embodiment is different from the preceding preferred embodiment in that inspection apertures 933 are formed in pairs at any side of an opening 931 of a carrier 93 of the current preferred embodiment, such that efficiency of inspection increases as the number of inspection apertures 933 increases.

As described in the aforesaid preferred embodiments of the present invention, given an inspection aperture formed in a carrier of the present invention, it is feasible to determine whether a gap formed between the carrier and substrate of the present invention is completely filled with an adhesive, by inspection with a naked eye instead of an auxiliary tool like a microscope. As indicated above, the present invention features can lower packaging cost and simply shorter process. Also, the present invention solves the drawbacks of the prior art, including the problems of a gap between a semiconductor device and a known carrier not completely filled with an adhesive and a molding compound escaping from the gap and flashing over to the back of a substrate during a known molding process. These problems lead to contamination of solder ball pads and compromise of yields of finished products.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a semiconductor device, comprising the steps of:
disposing a chip-mounted substrate in an opening of a carrier, the opening being slightly larger than the substrate to form a gap between the substrate and the carrier, forming at least a storage aperture and at least an inspection aperture at the periphery of the opening, and the at least a storage aperture and the at least an inspection aperture being spaced from one another;
infusing an adhesive into the storage aperture, filling the gap and the inspection aperture with the adhesive by capillarity rendered by the gap, and inspecting the inspection aperture to determine whether the inspection aperture is filled with the adhesive;
forming a molding compound to encapsulate the chip, the substrate, and the gap in whole and the carrier in part; and
performing a cutting operation on the molding compound and the substrate to form a semiconductor device with desirable dimensions.

2. The method of claim 1, wherein the storage aperture is larger than the inspection aperture.

3. The method of claim 1, wherein one of a radius and a side length of the inspection aperture is 3 to 10 times the width of the gap.

4. The method of claim 1, wherein the inspection aperture is formed at one of a corner and a side of the opening.

5. The method of claim 1, wherein one of the radius and the side length of the inspection aperture ranges from 0.15 to 2.0 mm.

6. The method of claim 5, wherein one of the radius and the side length of the inspection aperture is 1.0 mm.

7. The method of claim 1, wherein the inspection aperture is formed equidistantly between adjacent storage apertures.

8. The method of claim 1, wherein the chip is electrically connected to the substrate by flip chip technique.

9. The method of claim 1, wherein the adhesive is one of a solder mask and an epoxy resin.

10. The method of claim 1, wherein the adhesive secures the substrate in position in the opening of the carrier, and completely fills the gap between the substrate and the carrier.

11. The method of claim 1, further comprising performing an implantation process of solder ball, wherein a plurality of solder balls are disposed on the back of the substrate before or after the cutting operation.

12. A carrier for fabricating a semiconductor device with a plate structure as a carrier, comprising:
at least an opening;
at least a storage aperture formed at the periphery of the opening; and
at least an inspection aperture formed at the periphery of the opening, wherein the storage aperture is larger than the inspection aperture, and the storage aperture is spaced apart from the inspection aperture.

13. The carrier of claim 12, wherein one of a radius and a side length of the inspection aperture ranges from 0.15 to 2.0 mm.

14. The carrier of claim 13, wherein one of the radius and the side length of the inspection aperture is 1.0 mm.

15. The carrier of claim 12, wherein the inspection aperture is formed equidistantly between adjacent storage apertures.

16. The carrier of claim 12, wherein the inspection aperture is formed at one of a corner and a side of the opening.

17. The carrier of claim 12, wherein the opening receives a substrate allowing a gap to be formed therebetween, infusing an adhesive into the storage aperture, and filling the gap and the inspection aperture with the adhesive by capillarity rendered by the gap.
